(19) United States
(12) Patent Application Publication
(10) Pub. No.: US 2026/0047407 A1
(43) Pub. Date: Feb. 12, 2026

(54) METHOD OF WAFER ASSEMBLY BY MOLECULAR BONDING

(71) Applicants: STMicroelectronics France, Montrouge (FR); COMMISSARIAT A L'ENERGIE ATOMIQUE ET AUX ENERGIES ALTERNATIVES, Paris (FR)

(72) Inventors: Francois GUYADER, Montbonnot (FR); Pascal BESSON, Notre Dame de Mesage (FR)

(73) Assignees: STMicroelectronics France, Montrouge (FR); COMMISSARIAT A L'ENERGIE ATOMIQUE ET AUX ENERGIES ALTERNATIVES, Paris (FR)

(21) Appl. No.: 19/361,908

(22) Filed: Oct. 17, 2025

Related U.S. Application Data
(62) Division of application No. 17/384,418, filed on Jul. 23, 2021.

(30) Foreign Application Priority Data
Jul. 31, 2020 (FR) 2008208

(51) Int. Cl. H01L 21/20; H01L 21/3105; H01L 21/762; H10D 62/10

(52) U.S. Cl. CPC H01L 21/2007; H01L 21/31055; H01L 21/76251; H10D 62/124

(57) ABSTRACT

The present description concerns a method of manufacturing a first wafer, intended to be assembled to a second wafer by molecular bonding, including the successive steps of: forming a stack of layers at the surface of a substrate; and successive chemical etchings of the edges of said layers from the layer of the stack most distant from the substrate, across a smaller and smaller width.

### BACKGROUND

### Technical Field

The present disclosure generally concerns a method of assembly of two wafers by molecular bonding, also called direct bonding.

### Description of the Related Art

A method of manufacturing an electronic or optoelectronic device may include bonding to each other of semiconductor wafers by molecular bonding followed by a thinning or a cutting of one of the wafers. The wafers may have rounded edges at the level of which the molecular bonding cannot be properly performed. A weak area is generally created on and along edges of the wafers. During the thinning or cutting step, the edge of one of or of the two wafers may then break.

For certain applications, there is a need to improve this assembly to limit risks of ruptures that may result in the presence of polluting or contaminating elements, which may be incompatible with the cleanliness conditions for the subsequent use of equipment dedicated to the manufacturing of electronic components.

### BRIEF SUMMARY

An embodiment of the present disclosure overcomes all or part of the disadvantages of the previously-described methods of assembly of two wafers by molecular bonding.

An embodiment provides a method of manufacturing a first wafer, intended to be assembled to a second wafer by molecular bonding, including the successive steps of:
forming of a stack of layers at the surface of a substrate; and
successive chemical etchings of the edges of said layers from the layer of the stack most distant from the substrate, across a smaller and smaller width (e.g., a staircase like shape or structure).

According to an embodiment, the chemical etching of each layer of the stack comprises the application of an etching solution only on the edge to be etched of said layer.

According to an embodiment, the distance between the lateral edges of two successive layers in the stack is in the range or ranging from 30 μm to 200 μm, preferably from 50 μm to 100 μm.

According to an embodiment, the step of successive chemical etchings of the edges of said layers is followed by a step of forming of a step on the contour of the substrate.

According to an embodiment, the step is formed by chemical etching.

According to an embodiment, at least one of the chemical etchings comprises the use of a hydrogen fluoride solution.

According to an embodiment, at least one of the chemical etchings comprises the use of a hydrogen fluoride and nitric acid solution.

According to an embodiment, at least one of the chemical etchings comprises the use of a solution of tetramethylammonium hydroxide, of tetraethylammonium hydroxide, and/or of ammonia.

According to an embodiment, the step is formed by mechanical abrasion.

According to an embodiment, the step is formed in the substrate down to a depth in the range or ranging from 5 micrometers (μm) to 20 μm, preferably from 10 μm to 15 μm.

Another embodiment provides a method of forming an optoelectronic device comprising the molecular bonding of a first wafer, manufactured according to the method described hereabove, to a second wafer.

According to an embodiment, the method comprises, after the molecular bonding step, a step of thinning the first wafer.

Another embodiment provides a first wafer intended to be assembled to a second wafer by molecular bonding, the first wafer comprising a substrate and a stack of layers at the surface of the substrate, the edge of each layer of the stack being recessed with respect to the edge of the adjacent layer closest to the substrate.

According to an embodiment, at least one of said layers of the stack is a semiconductor layer.

According to an embodiment, at least one of said layers of the stack is a dielectric layer.

### BRIEF DESCRIPTION OF THE SEVERAL VIEWS OF THE DRAWINGS

The foregoing features and advantages, as well as others, will be described in detail in the following description of specific embodiments given by way of illustration and not limitation with reference to the accompanying drawings, in which:

FIG. 1 shows, in a partial simplified cross-section view, an example of assembly of two wafers by molecular bonding;

FIG. 2 shows, in a partial simplified cross-section view, an embodiment of a wafer adapted to a molecular bonding;

FIG. 3 illustrates, in a partial simplified cross-section view, a step of an embodiment of a method of manufacturing the wafer shown in FIG. 2;

FIG. 4 illustrates another step of the method;

FIG. 5 shows an implementation mode of a chemical etch step;

FIG. 6 illustrates another step of the method;

FIG. 7 illustrates another step of the method;

FIG. 8 illustrates another step of the method;

FIG. 9 illustrates another step of the method;

FIG. 10 illustrates another step of the method; and

FIG. 11 illustrates another step of the method.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the steps and elements that are useful for an understanding of the embodiments described herein have been illustrated and described in detail. In particular, the assembly of two wafers by molecular bonding has not been described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements. In the following disclosure, unless otherwise specified, when reference is made to absolute positional qualifiers, such as the terms “front,” “back,” “top,” “bottom,” “left,” “right,” etc., or to relative positional qualifiers, such as the terms “above,” “below,” “upper,” “lower,” etc., or to qualifiers of orientation, such as “horizontal,” “vertical,” etc., reference is made to the orientation shown in the figures.

Unless specified otherwise, the expressions “around,” “approximately,” “substantially” and “in the order of” signify within 10%, and preferably within 5%.

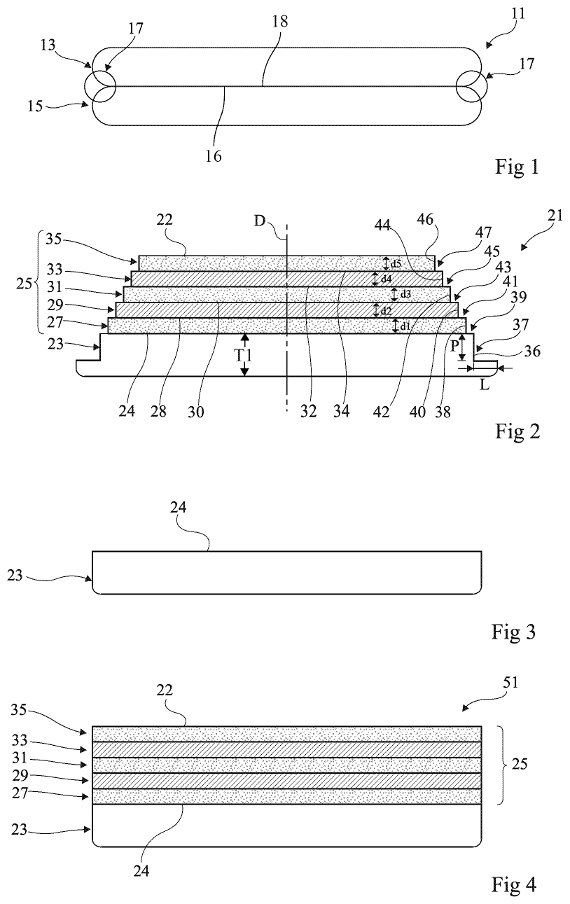

FIG. 1 shows, in a partial simplified cross-section view, a structure 11 including two wafers 13, 15 assembled to each other by molecular bonding. The first wafer 13 is stacked on the second wafer 15. Each wafer 13, 15, for example, corresponds to a semiconductor wafer adapted to the forming of integrated circuits. Structure 11 is, for example, obtained at an intermediate step of an electronic device manufacturing method.

Before the molecular bonding, a dielectric layer, for example, a silicon oxide layer, is formed on the surfaces 16, 18 of wafers 13, 15, respectively, intended to come into contact with each other during the molecular bonding, each of these surfaces 16, 18 being called contact surface hereafter. The molecular bonding starts when an area of the contact surface 16 of wafer 13 is placed into contact with the contact surface 18 of wafer 15. The bonding propagates to the rest of the opposite areas of the contact surfaces 16, 18, respectively. The step of molecular bonding may be followed by a step of thinning one of wafers 13, 15, respectively.

Each wafer 13, 15 generally includes a lateral edge having rounded corners, which can readily be seen at the left-hand side or the right-hand side of FIG. 1. Given this geometry, it is possible for the molecular bonding between the two wafers 13, 15 not to take place properly at the periphery (e.g., edges) of the wafers 13, 15. Structure 11 then includes an area 17, which are encircled in FIG. 1, present all along the periphery of the structure 11, within which the two wafers 13 and 15 are not bonded. Area 17 extends from the lateral edges of wafers 13 and 15, towards the centers of the wafers, over a distance in the order of several hundreds of micrometers (μm), in the order of one millimeter (mm), or even in the order of several millimeters (mm).

Area 17 is a mechanically weak area having pieces or portions that may break when one of wafers 13, 15 is submitted to a mechanical action such as a planarization or a cutting. These pieces or portions form pollutants or contaminants that may disturb the subsequent steps of the electronic device manufacturing method.

It is known to form a step on the contour of the contact surface 16, 18 of one of wafers 13, 15, respectively. Thereby, the contact surface of the wafer including the step is properly glued to the contact surface of the other wafer and the previously-described mechanically weak area is absent. However, the wafer including the step may include a stack of layers, including semiconductor layers, on the side of the contact surface, and these semiconductor layers may be used afterwards for the forming of electronic components. The forming of the step by sawing or grinding may cause the incorporation of polluting or contaminating elements in the semiconductor layers, the pollutants or contaminants particularly originating from the contact of these semiconductor layers with the grinding wheel or the saw.

FIG. 2 is a partial simplified cross-section view of an embodiment of a wafer 21 capable of being bonded to another wafer by molecular bonding, and which enables to obtain a bonded structure having no weak peripheral area.

According to the embodiment illustrated in FIG. 2, wafer 21 has a contact surface 22 intended to be bonded to another wafer by molecular bonding. The contact surface 22 and the wafer 21 may be the same or similar to the contact surfaces 16, 18, respectively, and the wafers 13, 15, respectively, as discussed earlier and shown in FIG. 1. Wafer 21 includes a substrate 23 having an upper surface 24 on which a stack 25 of layers has been formed and are present. Stack 25 includes, from bottom to top, in the orientation of FIG. 2 the following layers:
a dielectric layer 27 on top of and in contact with the upper surface 24 of substrate 23;
a semiconductor layer 29 on top of and in contact with the upper surface 28 of dielectric layer 27;
a dielectric layer 31 on top of and in contact with the upper surface 30 of semiconductor layer 29;
a semiconductor layer 33 on top of and in contact with the upper surface 32 of dielectric layer 31; and
a dielectric layer 35 on top of and in contact with the upper surface 34 of semiconductor layer 33, and the dielectric layer 35 delimiting the contact surface 22 of wafer 21.

According to the embodiment illustrated in FIG. 2, substrate 23 preferably has a thickness T1 in the range or ranging from 600 μm to 800 μm, for example, in the order of 775 μm. Preferably, the upper surface 24 of substrate 23 is planar. Preferably, substrate 23 substantially has a symmetry of revolution around an axis D, upper surface 24 then substantially corresponding to a disk. Substrate 23 may be made of a semiconductor material, for example, of silicon.

According to the embodiment illustrated in FIG. 2, substrate 23 includes a step 37 (e.g., a step like structure of a staircase) extending from upper surface 24 all along the periphery or edge of substrate 23 down a depth P and across a width L, depth P being measured along axis D and width L being measured radially with respect to the center of surface 24. Depth P is transverse to width L. Depth P of step 37 is preferably in the range or ranging from 5 μm to 20 μm, for example, from 10 μm to 15 μm. Width Lis, for example, in the range or ranging from 200 μm to 5 mm, preferably from 1 mm to 3 mm, more preferably in the order of 1.5 mm. Step 37 forms a step at the periphery of substrate 23.

According to the embodiment illustrated in FIG. 2, dielectric layer 27 preferably has a thickness d1 in the range or ranging from 20 nm (nanometers) to 30 nm, for example, in the order of 25 nm. Layer 27 is located on the upper surface 24 of substrate 23. Layer 27 covers the central portion of upper surface 24 so that the cylindrical lateral edge 38 of layer 27 and the cylindrical lateral edge 36 of the step 37 of substrate 23 are separated by a distance, measured radially with respect to axis D, from 30 μm to 200 μm, preferably from 50 μm to 200 μm, more preferably in the order of 100 μm. Wafer 21 then includes a step 39 between layer 27 and substrate 23. Layer 27 may be a silicon dioxide layer.

According to the embodiment illustrated in FIG. 2, semiconductor layer 29 preferably has a thickness d2 in the range or ranging from 20 nm to 40 nm, for example, in the order of 37 nm. Layer 29 is located on the upper surface 28 of layer 27. Layer 29 covers the central portion of upper surface 28 so that the cylindrical lateral edge 40 of layer 29 and the cylindrical lateral edge 38 of layer 27 are separated by a distance, measured radially with respect to axis D, from 30 μm to 200 μm, preferably from 50 μm to 100 μm, more preferably in the order of 100 μm. Wafer 21 then includes a step 41 between layer 27 and layer 29. Layer 29 may be a silicon layer, forming with substrate 23 and dielectric layer 27 a structure of silicon on insulator type (SOI).

According to the embodiment illustrated in FIG. 2, layer 31 preferably has a thickness d3 in the range or ranging from 20 nm to 30 nm, for example, in the order of 25 nm. Layer 31 is located on the upper surface 30 of layer 29. Layer 31 covers the central portion of upper surface 30 so that the cylindrical lateral edge 42 of layer 31 and the cylindrical lateral edge 40 of layer 29 are separated by a distance, measured radially with respect to axis D, from 30 μm to 200 μm, preferably from 50 μm to 100 μm, more preferably in the order of 100 μm. Wafer 21 then includes a step 43 between layer 29 and layer 31. Layer 31 may be made of silicon dioxide and may correspond to a thermal oxide.

According to the embodiment illustrated in FIG. 2, semiconductor layer 33 preferably has a thickness d4 in the range or ranging from 5 nm to 20 nm, for example, in the order of 15 nm. Layer 33 is located on the upper surface 32 of layer 31. Layer 33 covers the central portion of upper surface 32 so that the cylindrical lateral edge 44 of layer 33 and the cylindrical lateral edge 42 of layer 31 are separated by a distance, measured radially with respect to axis D, from 30 μm to 200 μm, preferably from 50 μm to 100 μm, more preferably in the order of 100 μm. Wafer 21 then includes a step 45 between layer 31 and layer 33. Layer 33 may be made of amorphous silicon.

According to the embodiment illustrated in FIG. 2, dielectric layer 35 preferably has a thickness d5 in the range or ranging from 10 nm to 30 nm, for example, in the order of 20 nm. Layer 35 is located on the upper surface 34 of layer 33. Layer 35 covers the central portion of upper surface 34 so that the cylindrical lateral edge 46 of layer 35 and the cylindrical lateral edge 44 of layer 33 are separated by a distance, measured radially with respect to axis D, ranging from 30 μm to 200 μm (e.g., may be any distance between 30 μm to 200 μm as well as being substantially equal to 30 μm or 200 μm), preferably ranging from 50 μm to 100 μm (e.g., may be any distance between 50 μm to 100 μm as well as being substantially equal to 50 μm or 100 μm), more preferably in the order of 100 μm. Wafer 21 then includes a step 47 between layer 33 and layer 35. Layer 35 may correspond to an undoped silicon glass layer (USG).

Steps 37, 39, 41, 43, 45, and 47 provide a pyramidal, also called “stepped,” geometry, to wafer 21. The steps 37, 39, 41, 43, 45, 47 may be step structures, and the steps together may be a staircase structure, a stepped structure, a plurality of step structures, or a plurality of successive step structure. During the molecular bonding operation, contact surface 22 is applied against the contact surface of another wafer to which it bonds by molecular bonding. The presence of steps 37, 39, 41, 43, 45, and 47 results in that contact surface 22 is properly bonded to the contact surface of the other wafer and the previously-described mechanically weak area is absent between the wafer 21 as well as the other wafer that are bonded together. Further, as described in further detail hereafter, at least steps 39, 41, 42, 45, and 47 are formed by chemical etching, without there to be a contact of layers 27, 29, 31, 33, and 35 with a sawing or grinding tool. Thus, a pollution of layers 27, 29, 31, 33, and 35 with pollutants or contaminations originating from the contact with a sawing or grinding tool is avoided.

The wafer 21 illustrated in FIG. 2 includes a stack 25 of five layers, however, in practice, stack 25 may include a number of layers different from five. For example, stack 25 may include two, three, four, six, or any number of layers as selected. Similarly, compositions of the layers and thicknesses of the layers have been mentioned in relation with FIG. 2. However, in practice, in some other embodiments, the compositions and the thicknesses of the layers may be different than those discussed in relation with FIG. 2.

FIGS. 3 to 11 are partial simplified cross-section views of structures obtained at successive steps of an embodiment of a method of manufacturing the wafer 21 illustrated in FIG. 2.

FIG. 3 is a cross-section view of an initial structure including substrate 23.

FIG. 4 shows a structure 51 obtained at the end of the forming of the layers 27, 29, 31, 33, and 35 forming stack 25, on the upper surface 24 of substrate 23. Layers 27, 29, 31, 33, and 35 are formed full plate, that is, each layer entirely covers the underlying layer.

Each layer 27, 29, 31, 33, and 35 is, for example, deposited by chemical vapor deposition (CVD), particularly by low-pressure chemical vapor deposition (LPCVD) or by plasma-enhanced chemical vapor deposition (PECVD).

When all the layers of stack 25 have been formed at the surface 24 of substrate 23, a plurality of etch steps are successively carried out to form steps 37, 39, 41, 43, 45, and 47 at the periphery of layers 23, 27, 29, 31, 33, and 35. The structures obtained at the end of the etch steps are illustrated in relation with FIGS. 6 to 11.

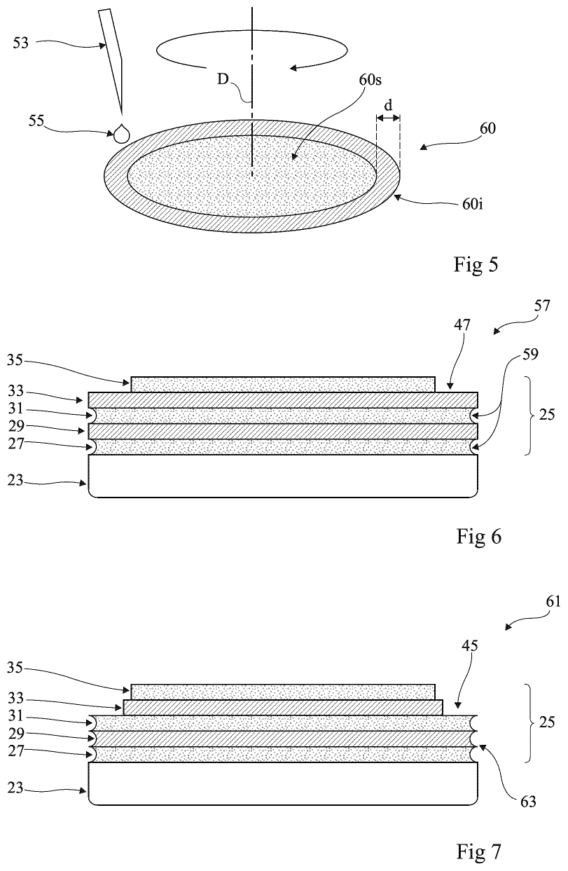

According to an embodiment, each step 37, 39, 41, 43, 45, and 47 is formed by a chemical etching method such as illustrated in FIG. 5.

FIG. 5 shows an embodiment of a chemical etch step where the etching is performed by local deposition of an etching solution 55 on a wafer 60 by means of a nozzle 53 having a controlled flow, while wafer 60 is rotating around an axis D. Etching solution 55 then acts with the layer(s) exposed at the wafer surface. As an example, the deposition of etching solution 55 causes the etching of an upper layer 60s of the wafer 60 to expose an underlying layer 60i of the wafer 60.

The deposition of solution 55 is performed locally at the periphery of wafer 60, on a ring having a width d, measured radially, from the lateral edge of wafer 60. Width d may vary according to the position of the layers to be etched in stack 25. Preferably, the closer the layer to be etched is to the contact surface of wafer 60, the greater distance d. The contact surface of the wafer 60 is the same or similar to the contact surface 22 of the wafer 21 as discussed earlier and shown in FIG. 2.

The deposited solution 55 particularly depends on the composition of the layer(s) to be etched.

For example, the solution 55 may be based on hydrofluoric acid (HF) when the layer to be etched is made of silicon oxide or based on hydrofluoric acid (HF) and on ammonium fluoride (NH₄F), forming a BOE-type (“Buffered Oxide Etch”) solution.

For example, the solution 55 may be based on a mixture of hydrofluoric acid and of nitric acid (HNO₃) associated, for example, with orthophosphoric acid to form a HNP-type solution and with sulfuric acid to form a HNPS-type solution for an isotropic etching of a silicon layer; and/or may be based on tetramethylammonium hydroxide (TMAH), on tetraethylammonium hydroxide (TEAH), and/or on potassium hydroxide (KOH) and/or on ammonia (NH₄OH) for an anisotropic etching of a silicon layer.

The concentration of each of the components of solution 55 is adapted to obtain the desired etch speed. As an example, the mass concentration of TMAH is in the range or ranging from 2% to 25%, the mass concentration of TEAH is in the range or ranging from 5% to 30%, the mass concentration of KOH is in the range or ranging from 15% to 40%, and the mass concentration of ammonia is in the range or ranging from 15% to 40%.

According to an embodiment, solution 55 is deposited at the surface of wafer 60 with a flow substantially smaller than 100 mL/min (milliliter per minute), preferably in the order of 18 mL/min.

In FIG. 5, a single nozzle 53 delivering etch solution 55 has been shown. As a variant, a plurality of nozzles 53 may be provided, each nozzle 53 delivering one component of etch solution 55, the mixture of these components forming etch solution 55. As a variant, each nozzle 53 enables to dispense a different etching solution 55. Nozzle(s) 53 may be located on an arm, not shown, configured to displace nozzles 53 with respect to axis D of wafer 60.

According to an embodiment, other nozzles may be provided, for example, to supply deionized water that may be used as a rinsing solution and enable to stop the etching at the appropriate time, or to supply an inert gas such as nitrogen that may be used to dry the wafer after rinsing and/or avoid liquid phase returns to the inside of the wafer on its critical external portion.

This etch step may be carried out under an inert atmosphere, for example, under nitrogen, particularly if the layers to be etched are sensitive to corrosion effects. For silicon or silicon oxide layers, it is not necessary for this step to take place under an inert atmosphere.

According to another embodiment, certain etch steps (particularly the steps of etching of the most superficial layers, that is, layers 31, 33, and 35) each include the forming of a mask on the wafer, particularly by photolithography steps, the mask only covering the portion of the wafer which is not to be etched at this etch step, the deposition of the etching solution to etch the portion of the upper layer which is not protected by the mask, and the removal of the mask.

FIG. 6 shows a structure 57 obtained after the removal of a peripheral portion of layer 35 of the stack 25 of the structure 51 shown in FIG. 5, along the entire height of layer 35, to form step 47.

The removal of the peripheral portion of layer 35 may be performed by the method previously described in relation with FIG. 5. The etching solution 55 used to etch the peripheral portion of layer 35 is preferably based on hydrogen fluoride (HF).

The etching is performed over a distance from the lateral edge of substrate 23 (that is, the distance d shown in FIG. 5) in the range or ranging from 350 μm (5×30+200 μm) to 6 mm (5×200+5,000 μm), preferably in the order of 2 mm (5×100+1,500 μm).

Structure 57 may include recesses 59 on the edges of layers 31 and 27. Indeed, etching solution 55 is adapted to the chemical nature of the layer to be etched exposed on the upper surface of structure 51 shown in FIG. 4. However, if a plurality of layers are of same chemical nature as the layer exposed at the surface, these layers may also be etched during the etching of the layer exposed at the surface. However, since these layers are only exposed on a small surface area, that is, the lateral edge of these layers, the etching of these layers remains limited.

FIG. 7 shows a structure 61 obtained after the removal of a peripheral portion of layer 33 of the stack 25 of the structure 57 shown in FIG. 6, along the entire height of layer 33 to form step 45.

The removal of the peripheral portion of layer 33 may be performed by the method previously described in relation with FIG. 5. Even if an isotropic etching is possible, an anisotropic etching which has a better etch selectivity over the underlying oxide will rather be preferred at this stage. The etching solution 55 used to perform the etching of the peripheral portion of layer 33 is preferably based on HF, HNO₃, HNP, or HNPS.

The etching is performed over a distance from the lateral edge of substrate 23 (that is, the distance d shown in FIG. 5), in the range or ranging from 320 μm (4×30+200 μm) to 5.8 mm (4×200+5,000 μm), preferably in the order of 1.9 mm (4×100+1,500 μm).

Structure 61 may include a recess 63 on the edge of layer 29. Indeed, since layer 29 may be of same chemical nature as layer 33, the step of etching a peripheral portion of layer 33 may also cause an etching of the edge of layer 29.

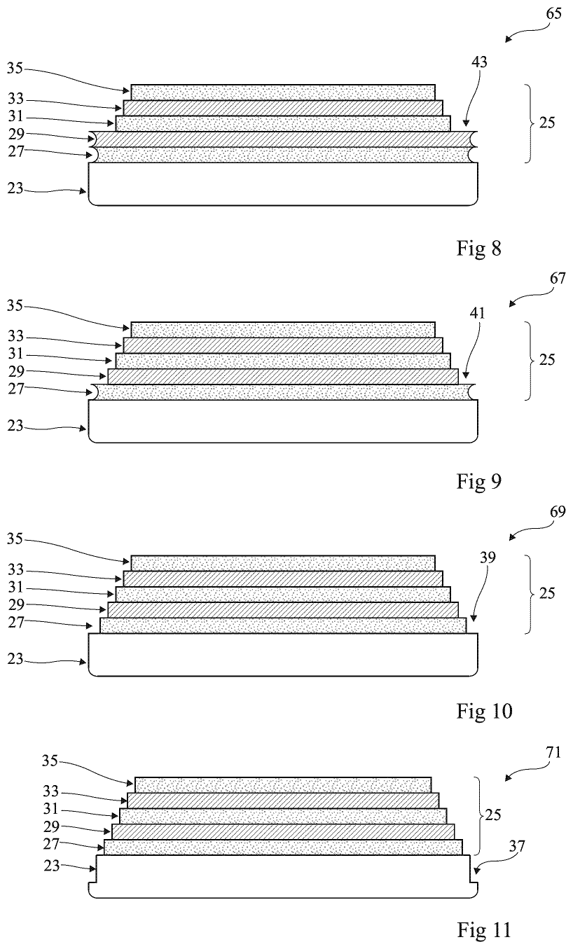

FIG. 8 shows a structure 65 obtained after the removal of a peripheral portion of layer 31 of the stack 25 of the structure 61 shown in FIG. 5, along the entire height of layer 31 to form step 43.

The removal of the peripheral portion of layer 31 may be performed by the method previously described in relation with FIG. 5. The etching solution 55 used to perform the etching of the peripheral portion of layer 31 is preferably based on HF.

The etching is performed over a distance from the lateral edge of substrate 23 (that is, the distance d shown in FIG. 5), in the range or ranging from 290 μm (3×30+200 μm) to 5.6 mm (3×200+5,000 μm), preferably in the order of 1.8 mm (3×100+1,500 μm). The step of etching a peripheral portion of layer 31 may also cause an etching of the edge of layer 27.

FIG. 9 shows a structure 67 obtained after the removal of a peripheral portion of the layer 29 of stack 25 of the structure 65 illustrated in FIG. 8, along the entire height of layer 29, to form step 41.

The removal of the peripheral portion of semiconductor layer 29 may be performed by the method previously described in relation with FIG. 5. Even if an anisotropic etching is possible, an anisotropic etching which has a better etch selectivity over the underlying oxide will rather be preferred at this stage. The etching solution 55 used to perform the etching of the peripheral portion of layer 29 is preferably based on HF, HNO₃, HNP, or HNPS.

The etching is performed over a distance from the lateral edge of substrate 23 (that is, the distance d shown in FIG. 5), in the range or ranging from 260 μm (2×30+200 μm) to 5.4 mm (2×200+5,000 μm), preferably in the order of 1.7 mm (2×100+1,500 μm).

FIG. 10 shows a structure 69 obtained after the removal of a peripheral portion of layer 27 of stack 25 of the structure 67 illustrated in FIG. 9, along the entire height of layer 27, to form step 39.

The removal of the peripheral portion of layer 27 may be performed by the method previously described in relation with FIG. 5. The etching solution 55 used to perform the etching of the peripheral portion of the layer is preferably based on HF.

The etching is performed over a distance from the lateral edge of substrate 23 (that is, the distance d shown in FIG. 5), in the range or ranging from 230 μm (30+200 μm) to 5.2 mm (200+5,000 μm), preferably in the order of 1.6 mm (100+1,500 μm).

FIG. 11 shows a structure 71 obtained after the forming of step 37 in the substrate 23 of the structure 69 illustrated in FIG. 10.

Step 37 is, according to an embodiment, formed by the method previously described in relation with FIG. 5. Even if an anisotropic etching is possible, an isotropic etching which has a higher etch speed will rather be preferred at this stage and this, given the significant thickness to be etched. The etching solution 55 used to form step 37 is preferably based on TMAH, TEAH, KOH, or NH₄OH. The etching is performed over a distance from the lateral edge of the lower surface of substrate 23 (that is, the distance d shown in FIG. 5) in the range or ranging from 200 μm to 5 mm, preferably in the order of 1.5 mm.

According to another embodiment, step 37 is formed by a mechanical cutting method, using a saw and/or a grinding wheel. The use of a grinding or sawing tool causes no contamination of layers 27, 29, 31, 33, 35 since the grinding or sawing tool does not come into contact with these layers 27, 29, 31, 33, 35 due to steps 39, 41, 42, 45, 47.

An advantage of the described embodiments is that they enable to ensure a proper bonding between two wafers and thus decrease risks of forming of a weak area likely to break during a subsequent planarization step.

Another advantage of the described embodiments is that they enable to limit metallic contamination at the surface of the stack of layers. It is then possible to form circuits inside and on top of the wafers thus formed.

Another advantage of the described embodiments is that the successive forming of steps 39, 41, 42, 45, 47 ensures that the lateral edge of none of layers 27, 29, 31, 33, 35 is cantilevered with respect to the neighboring layers, which would cause the forming of a weak area likely to break.

Various embodiments and variants have been described. Those skilled in the art will understand that certain features of these various embodiments and variants may be combined, and other variants will occur to those skilled in the art.

Finally, the practical implementation of the described embodiments and variations is within the abilities of those skilled in the art based on the functional indications given hereabove.

A method of manufacturing a first wafer (21), intended to be assembled to a second wafer by molecular bonding may be summarized as including the successive steps of: forming a stack (25) of layers (27, 29, 31, 33, 35) at the surface of a substrate (23); and successive chemical etchings of the edges of said layers from the layer of the stack most distant from the substrate, across a smaller and smaller width.

The chemical etching of each layer (27, 29, 31, 33, 35) of the stack (25) may include the application of an etching solution (55) only on the edge to be etched of said layer. The distance between the lateral edges of two successive layers (27, 29, 31, 33, 35) in the stack (25) may be in the range from 30 micrometers (μm) to 200 μm, preferably from 50 μm to 100 μm. The step of successive chemical etchings of the edges of said layers (27, 29, 31, 33, 35) may be followed by a step of forming of a step (37) on the contour of the substrate (23). The step (37) may be formed by chemical etching. At least one of the chemical etchings may include the use of a hydrogen fluoride solution. At last one of the chemical etchings may include the use of a hydrogen fluoride and nitric acid solution. At least one of the chemical etchings may include the use of a solution of tetramethylammonium hydroxide, of tetraethylammonium hydroxide, and/or of ammonia. The step (37) may be formed by mechanical abrasion. The step (27) may be formed in the substrate (23) down to a depth in the range from 5 μm to 20 μm, preferably from 10 μm to 15 μm.

A method of forming an optoelectronic device may be summarized as including the molecular bonding of a first wafer (21) to a second wafer. The first wafer may be manufactured according to the method of manufacturing the first wafer (21) as summarized above and is intended to be assembled to a second wafer,

The method of forming an optoelectronic device, may further include, after the molecular bonding step, a step of thinning the first wafer (21).

A first wafer (21) intended to be assembled to a second wafer by molecular bonding, may be summarized as the first wafer including a substrate (23) and a stack (25) of layers (27, 29, 31, 33, 35) at the surface of the substrate (23), the edge of each layer of the stack being recessed with respect to the edge of the adjacent layer closest to the substrate.

At least one of said layers (27, 29, 31, 33, 35) of the stack (25) may be a semiconductor layer (29, 33). At least one of said layers (27, 29, 31, 33, 35) of the stack (25) may be a dielectric layer (35, 31, 27).

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A device, comprising:
a substrate including a step structure having a first depth along a first direction and a first width along a second direction transverse to the first direction; and
a stack of layers on a first surface of the substrate, the stack of layers including:
a first dielectric layer on the first surface, the first dielectric layer having a second depth along the first direction smaller than the first depth and smaller than the first width;
a first semiconductor layer on the first dielectric layer, the first semiconductor layer having a third depth along the first direction smaller than the first depth and smaller than the first width; and
a second dielectric layer on the first semiconductor layer, the second dielectric layer having a fourth depth along the first direction smaller than the first depth and smaller than the first width,
wherein each layer of the stack of layers has a width along the second direction greater than a width of each layer further from the substrate along the first direction.

2. The device according to claim 1, comprising:
a second semiconductor layer on the second dielectric layer, the second semiconductor layer having a fifth depth along the first direction smaller than the first depth and smaller than the first width.

3. The device according to claim 2, comprising:
a third dielectric layer on the second semiconductor layer, the third dielectric layer having a sixth depth along the first direction smaller than the first depth and smaller than the first width.

4. The device according to claim 1, wherein the substrate and each layer of the stack of layers are symmetrical along a center axis that extends along the first direction.

5. The device according to claim 1, wherein the first depth is in the range of 5 μm and 20 μm and the first width is in the range of 200 μm and 5 mm.

6. The device according to claim 5, wherein the second depth is in the range of 20 nm and 30 nm, the third depth is in the range of 20 nm and 40 nm, and the fourth depth is in the range of 20 nm and 30 nm.

7. The device according to claim 1, wherein the stack of layers and the substrate have a staircase structure.

8. The device according to claim 3, wherein the first and second dielectric layers include silicon dioxide and the first and second semiconductor layers include silicon.

9. The device according to claim 8, wherein the third dielectric layer is an undoped silicon glass layer.

10. A device, comprising:
a substrate including a step structure having a first depth along a first direction and a first width along a second direction transverse to the first direction; and
a stack of layers on a first surface of the substrate, the stack of layers including:
a first layer on the first surface, the first layer having a second depth along the first direction smaller than both the first depth and the first width, individually; and
a second layer on the first layer, the second layer having a third depth along the first direction smaller than both the first depth and the first width, individually;
wherein the first and second layers and the substrate are each symmetrical along a center axis that extends along the first direction, the first and second layers having a staircase structure.

11. The device according to claim 10, wherein the first layer is a dielectric layer and the second layer is a semiconductor layer.

12. The device according to claim 11, wherein the stack of layers includes:
a third layer on the second layer, the third layer having a second depth along the first direction smaller than both the first depth and the first width, individually; and
a fourth layer on the third layer, the fourth layer having a second depth along the first direction smaller than both the first depth and the first width, individually,
wherein the first layer extends a first distance from the central axis along the second direction greater than a second distance that the second layer extends from the central axis, and the second distance is greater than a third distance that the third layer extends from the central axis.

13. A device, comprising:
a first wafer including:
a substrate having a surface and a first edge;
a center axis transverse to the surface of the substrate; and
a stack of layers at the surface of the substrate, the stack of layers including:
a first layer on the surface of the substrate, the first layer having a second edge; and
a second layer on the first layer, the second layer having a third edge further away from the second edge than the first edge in a first direction transverse to the center axis.

14. The device according to claim 13, wherein at least one layer of the stack of layers is a semiconductor layer.

15. The device according to claim 13, wherein at least one layer of the stack of layers of the stack is a dielectric layer.

16. The device according to claim 13, wherein the substrate includes a step structure at the first edge.

17. The device of claim 16, wherein:
the substrate includes a thickness extending in a second direction transverse to the first direction; and
the step structure including a depth extending in the second direction, the depth being less than the thickness.

18. The device according to claim 13, wherein the stack of layers and the substrate have a staircase structure.

19. The device according to claim 13, further comprising a second wafer coupled to the first wafer.

20. The device of claim 19, wherein the second wafer is molecularly coupled to the stack of layers of the first wafer.
